(19) United States
(12) Patent Application Publication
(10) Pub. No.: US 2015/0303103 A1
(43) Pub. Date: Oct. 22, 2015

(54) CATALYST ADSORPTION METHOD AND CATALYST ADSORPTION DEVICE

(71) Applicants: Shoso Shinguhara, Osaka (JP); Fumihiro Inoue, Osaka (JP); Hiroshi Miyake, Osaka (JP); Ryohei Arima, Osaka (JP); Mitsuaki Iwashita, Nirasaki-shi, Yamanashi (JP); Takashi Tanaka, Nirasaki-shi, Yamanashi (JP)

(72) Inventors: Shoso Shinguhara, Osaka (JP); Fumihiro Inoue, Osaka (JP); Hiroshi Miyake, Osaka (JP); Ryohei Arima, Osaka (JP); Mitsuaki Iwashita, Nirasaki-shi, Yamanashi (JP); Takashi Tanaka, Nirasaki-shi, Yamanashi (JP)

(73) Assignees: TOKYO ELECTRON LIMITED, Tokyo (JP); A SCHOOL CORPORATION KANSAI UNIVERSITY, Osaka (JP)

(21) Appl. No.: 14/343,509

(22) PCT Filed: Aug. 8, 2012
(86) PCT No.: PCT/JP2012/070230

§ 371 Date: Mar. 10, 2014

(30) Foreign Application Priority Data
Sep. 9, 2011 (JP) 2011-197510

(51) Int. Cl. H01L 21/768; C23C 18/16

(52) U.S. Cl. CPC H01L 21/76874; C23C 18/1619

(57) ABSTRACT

A catalyst adsorption method can sufficiently adsorb a catalyst to a lower portion of a recess formed in a substrate. A substrate 20 in which a recess 22 is formed is prepared. Then, a catalyst 23 formed of nanoparticles coated with a dispersant is adsorbed to a surface of the substrate 20 by bringing the substrate 20 into contact with a catalyst solution 12 containing the catalyst by a catalyst adsorption device 10. At that time, a high frequency vibration is applied to the catalyst solution 12.

### TECHNICAL FIELD

The embodiments described herein pertain generally to an adsorption method of adsorbing a catalyst to a recess of a substrate and an adsorption device therefor.

### BACKGROUND

Recently, semiconductor devices such as a LSI or the like have been required to have higher density in order to respond to a demand for reducing the packaging space or for improving the processing rate. As an example of a technology that achieves high density, there has been known a multilayer wiring technology of manufacturing a multilayer substrate, such as a three-dimensional LSI or the like, by stacking multiple wiring substrates.

According to the multilayer wiring technology, a through-via-hole, which penetrates the wiring substrates and in which a conductive material such as copper is buried, is typically formed in the wiring substrates in order to obtain electrical connection between the wiring substrates. As an example of a technology for forming the through-via-hole in which a conductive material is buried, there has been known an electroless plating method.

By way of example, in Patent Document 1, as a specific method of manufacturing a wiring substrate, there has been suggested a method in which a substrate including a recess is prepared, a palladium catalyst is adsorbed onto the substrate, and then, the substrate is immersed in a copper plating solution to form a copper plating layer within the recess. The substrate in which the copper plating layer is formed becomes thinned by a polishing method such as a chemical mechanical polishing method, so that a wiring substrate including a through-via-hole in which copper is buried can be manufactured.

Meanwhile, in recent years, a diameter of a through-via-hole becomes decreased in order to achieve high density of semiconductor devices. Therefore, it becomes more difficult to sufficiently adsorb a catalyst to a lower portion of a recess formed in a substrate.

As an example of a method of treating a recess having a high aspect ratio, Patent Document 2 suggests a method of filling a recess with a material, such as copper, having a low electrical resistance while applying a high frequency vibration to fine particles formed of the material. Although the method suggested in Patent Document 2 is not a method of adsorbing a catalyst to a recess but a method of filling a recess with a material, it has been described herein for reference.

### REFERENCES

Patent Document 1: Japanese Patent Laid-open Publication No. 2010-185113

Patent Document 2: Japanese Patent Laid-open Publication No. H11-097392

### DISCLOSURE OF THE INVENTION

### Problems to be Solved by the Invention

It is generally known that a fine particle has a high ratio of a surface area to a volume, so that agglomeration is likely to occur. Therefore, it is assumed that when a high frequency vibration is applied to a catalyst solution containing fine particles constituting a catalyst, the fine particles agglomerate together, so that adsorption of the fine particles to a side surface of a recess is suppressed.

### Means for Solving the Problems

In view of the foregoing problems, example embodiments provide a catalyst adsorption method and a catalyst adsorption device capable of effectively solving the problems.

In accordance with a first example embodiment, a catalyst adsorption method includes preparing a substrate in which a recess is formed; and adsorbing a catalyst formed of nanoparticles coated with a dispersant to a surface of the substrate by bringing the substrate into contact with a catalyst solution containing the catalyst. Further, in the adsorbing of the catalyst, a high frequency vibration is applied to the catalyst solution.

In accordance with a second example embodiment, a catalyst adsorption device includes a substrate holding unit configured to hold a substrate in which a recess is formed; a catalyst solution supplying unit configured to supply a catalyst solution containing a catalyst formed of nanoparticles coated with a dispersant to the substrate to bring the substrate into contact with the catalyst solution; and a high frequency vibrating unit configured to apply a high frequency vibration to the catalyst solution supplied to the substrate.

### Effect of the Invention

In accordance with a catalyst adsorption method and a catalyst adsorption device of example embodiments, a high frequency vibration is applied to a catalyst solution containing a catalyst formed of nanoparticles coated with a dispersant. Therefore, it is possible to sufficiently adsorb the catalyst to the entire side surface of a recess in a short time.

### BRIEF DESCRIPTION OF THE DRAWINGS

FIG. 1 is a block diagram illustrating a wiring forming system in accordance with an example embodiment.

FIG. 2 is a longitudinal cross sectional view illustrating a catalyst adsorption device in accordance with the example embodiment.

FIG. 3A to FIG. 3D illustrate a method of manufacturing a wiring substrate in accordance with the example embodiment.

FIG. 4A to FIG. 4D illustrate a method of manufacturing a wiring substrate in accordance with a first modification example of the example embodiment.

FIG. 5A to FIG. 5C illustrate a method of manufacturing a wiring substrate in accordance with a second modification example of the example embodiment.

FIG. 6 illustrates an observation result of a state of catalysts adsorbed to a side surface of a recess of a substrate in accordance with an experimental example 1.

FIG. 7 illustrates an observation result of a state of catalysts adsorbed to a side surface of a recess of a substrate in accordance with a comparative example 1.

FIG. 8A to FIG. 8C illustrate relations between an adsorption time and a density of the catalysts adsorbed to the side surface of the recess of the substrate in the experimental example 1 and the comparative example 1.

FIG. 9 illustrates an observation result of a state of catalysts adsorbed to a side surface of a recess of a substrate in accordance with an experimental example 2.

FIG. 10 illustrates an observation result of a state of catalysts adsorbed to a side surface of a recess of a substrate in accordance with an experimental example 3.

FIG. 11 illustrates an observation result of a state of catalysts adsorbed to a side surface of a recess of a substrate in accordance with a comparative example 2.

FIG. 12 illustrates an observation result of a state of catalysts adsorbed to a side surface of a recess of a substrate in accordance with a comparative example 3.

FIG. 13 illustrates an observation result of a state of a recess of a substrate before catalysts are adsorbed to the recess.

### MODE FOR CARRYING OUT THE INVENTION

(Wiring Forming System)

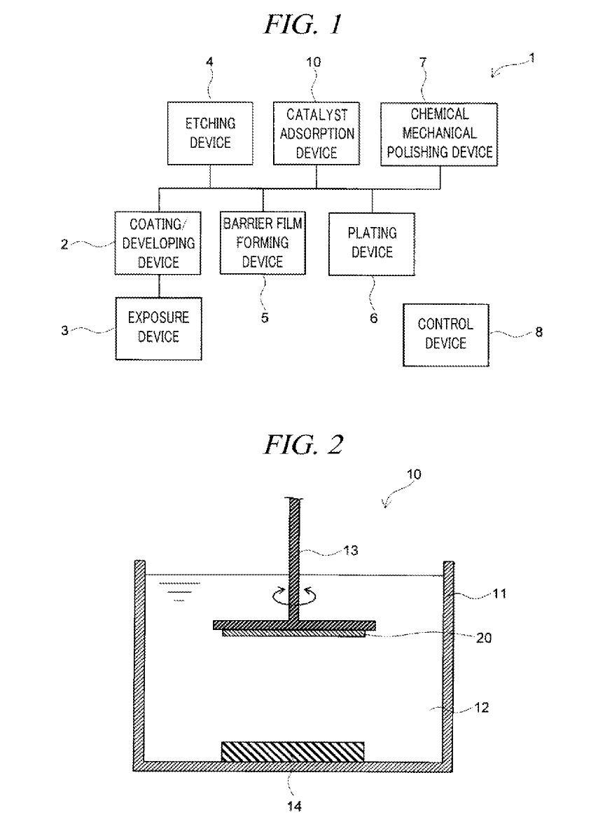

Hereinafter, example embodiments will be explained with reference to FIG. 1 to FIG. 4D. Referring to FIG. 1, a wiring forming system 1 of a semiconductor device will be explained first. FIG. 1 is a block diagram illustrating the wiring forming system 1 in accordance with the present example embodiment.

As depicted in FIG. 1, the wiring forming system 1 includes a catalyst adsorption device 10, a plating device 6, and a chemical mechanical polishing device 7. The catalyst adsorption device 10 is configured to adsorb a catalyst to a surface of a substrate in which a recess is formed, and the plating device 6 is configured to form a plating layer on the surface of the substrate to which the catalyst is adsorbed. Further, the chemical mechanical polishing device 7 is configured to chemically and mechanically polish the substrate on which the plating layer is formed to make the substrate thinned. As a result, a wiring substrate on which the plating layer is formed and which includes a through-via-hole is manufactured.

Further, as depicted in FIG. 1, the wiring forming system 1 may further include a coating/developing device 2, an exposure device 3, an etching device 4, or a barrier film forming device 5. The coating/developing device 2, the exposure device 3, and the etching device 4 are configured to form an insulating layer on the substrate and form a recess in the insulating layer. Further, the barrier film forming device 5 is configured to form a barrier film that suppresses a metal element constituting the plating layer formed on the substrate from being permeated through the substrate (for example, into the insulating layer).

(Catalyst Adsorption Device)

Hereinafter, the above-described catalyst adsorption device 10 will be explained in detail with reference to FIG. 2. FIG. 2 is a longitudinal cross sectional view illustrating the catalyst adsorption device 10.

The catalyst adsorption device 10 includes a substrate holding unit 13 configured to hold a substrate 20 in which a recess is formed, a catalyst solution supplying unit configured to supply a catalyst solution 12 containing a catalyst formed of nanoparticles to the substrate 20, and a high frequency vibration unit configured to apply a high frequency vibration to the catalyst solution 12 supplied to the substrate 20. In the present example embodiment, as depicted in FIG. 2, the catalyst solution supplying unit includes a catalyst solution tank 11 in which the catalyst solution 12 is stored, and a supplying line (not illustrated) through which the catalyst solution 12 is supplied to the catalyst solution tank 11. Further, as depicted in FIG. 2, the high frequency vibration unit includes a high frequency oscillator 14, such as an ultrasonic oscillator, provided within the catalyst solution tank 11. As indicated by an arrow in FIG. 2, the substrate holding unit 13 may be configured to be rotatable in the catalyst solution 12. Thus, the catalyst solution 12 within the catalyst solution tank 11 can be convected.

The present inventors have repeated experiments with close attention and found that when a high frequency vibration is applied to the catalyst solution 12 supplied to the substrate 20, the catalyst can be sufficiently adsorbed to the entire side surface of the recess of the substrate 20 in a short time, as supported by results of experimental examples to be described below. For this reason, in accordance with the present example embodiment, a time required for an adsorption process of adsorbing the catalyst to the surface of the substrate 20 can be reduced as compared with a conventional example. Further, the catalyst can be more securely adsorbed to the entire side surface of the recess of the substrate 20. For this reason, in a subsequent plating process, a plating layer can be more securely formed on the entire side surface of the recess of the substrate 20.

Hereinafter, there will be explained a modeling in which adsorption of the catalyst to the recess of the substrate 20 can be accelerated by applying a high frequency vibration to the catalyst solution 12. However, the present example embodiment is not limited thereto.

In the adsorption process of adsorbing the catalyst to the side surface of the recess of the substrate 20, the catalyst in the catalyst solution 12 is diffused or moved to the vicinity of the side surface of the recess of the substrate 20, and then, the catalyst is adsorbed to the side surface of the recess of the substrate 20. As a principle of diffusion or movement of the catalyst in the catalyst solution 12, a principle caused by concentration gradient of the catalyst or convection of the catalyst solution 12, or a principle caused by random movement of the catalyst can be assumed. Herein, in accordance with the present example embodiment, as described above, a high frequency vibration is applied to the catalyst solution 12 by the high frequency oscillator 14. For this reason, the high frequency vibration may accelerate the random movement of the catalyst. By way of example, a frequency of the random movement of the catalyst can be increased. For this reason, in accordance with the present example embodiment, it is possible to accelerate diffusion of the catalyst in the catalyst solution 12, so that it is possible to adsorb the catalyst to a lower portion of the recess of the substrate 20 in a short time even if a diameter of the recess is small.

A frequency of the high frequency vibration applied to the catalyst solution 12 by the high frequency vibration unit is appropriately set such that the catalyst can reach the lower portion of the recess of the substrate 20 in a desired time, and may be set to be in the range of, for example, about 1 kHz to about 1 MHz. Since a frequency of the high frequency vibration is set to be about 1 kHz or more, it is possible to sufficiently accelerate the random movement of the catalyst in the catalyst solution 12, and, thus, the catalyst can reach the lower portion of the recess of the substrate 20 in a short time. Further, since a frequency of the high frequency vibration is set to be about 1 MHz or less, it is possible to accelerate diffusion of the catalyst in the catalyst solution 12 without damage to various patterns formed on the substrate 20, for example, a pattern of the insulating layer.

An operation of the catalyst adsorption device 10 configured as described above is controlled by various programs recorded in a storage medium, and, thus, various processes are performed on the substrate 20. Herein, the storage medium stores therein various setting data or various programs such as a catalyst adsorption process program to be described below. As the storage medium, there may be used a computer-readable memory such as a ROM or a RAM, or a disk-type storage medium such as a hard disk, a CD-ROM, DVD-ROM, or a flexible disk, as commonly known in the art.

(Catalyst Solution and Catalyst)

Hereinafter, the catalyst solution 12 to be supplied to the substrate 20 and the catalyst contained in the catalyst solution 12 will be explained. The catalyst will be explained first.

As the catalyst adsorbed to the substrate 20, a catalyst having catalysis to accelerate a plating reaction may be appropriately used. By way of example, a catalyst formed of nanoparticles may be used. Herein, the nanoparticle means a particle that has catalysis and has an average particle diameter of about 20 nm or less and, for example, in the range of about 0.5 nm to about 20 nm. By way of example, an element constituting the nanoparticles may include palladium, gold, platinum, and the like.

Further, as the element constituting the nanoparticles, ruthenium may be used.

A method of measuring an average particle diameter of nanoparticles is not particularly limited, and various methods may be used. By way of example, when an average particle diameter of the nanoparticle in the catalyst solution 12 is measured, a dynamic light scattering method or the like may be used. The dynamic light scattering method is a technique of measuring an average particle diameter of the nanoparticle by irradiating a laser beam to the nanoparticle dispersed in the catalyst solution 12 and measuring a scattered light thereof. Further, when an average particle diameter of the nanoparticles adsorbed to the recess of the substrate 20 is measured, a preset number of nanoparticles, for example, twenty nanoparticles, are detected from an image obtained by using TEM or SEM, and then, the mean of particle diameters of these nanoparticles may be calculated.

Hereinafter, the catalyst solution 12 containing the catalyst formed of the nanoparticles will be explained. The catalyst solution 12 contains ions of the metal constituting the nanoparticles that form the catalyst. By way of example, if palladium constitutes the nanoparticles, the catalyst solution 12 contains palladium compounds, for example, palladium chloride, as palladium ion sources.

A composition of the catalyst solution 12 is not particularly limited. However, desirably, a composition of the catalyst solution 12 is set such that a viscosity coefficient of the catalyst solution 12 is about 0.01 Pa·s or less. Since the viscosity coefficient of the catalyst solution 12 is in the above-described range, the catalyst solution 12 can be sufficiently diffused to the lower portion of the recess of the substrate 20 even if a diameter of the recess of the substrate 20 is small. Thus, it is possible to more securely adsorb the catalyst to the lower portion of the recess of the substrate 20.

Desirably, the catalyst of the catalyst solution 12 is coated with a dispersant. Thus, surface energy of the catalyst can be reduced. Therefore, it is assumed that diffusion of the catalyst in the catalyst solution 12 can be further accelerated, so that the catalyst can reach the lower portion of the recess of the substrate 20 in a shorter time. Further, it is assumed that an increase in diameter of the catalyst caused by agglomeration of multiple catalysts can be suppressed, so that diffusion of the catalyst in the catalyst solution 12 can be further accelerated.

A method of preparing a catalyst coated with a dispersant is not particularly limited. By way of example, a catalyst solution containing a catalyst which is previously coated with a dispersant may be supplied to the catalyst adsorption device 10. Otherwise, the catalyst adsorption device 10 may be configured to coat the catalyst with the dispersant within the catalyst adsorption device 10, for example, in the catalyst solution supplying unit.

To be specific, as the dispersant, polyvinylpyrrolidone (PVP), polyacrylic acid (PAA), polyethyleneimine (PEI), tetramethylammonium (TMA), citric acid, or the like may be desirably used.

Besides, the catalyst solution 12 may contain various chemical materials for adjusting characteristics thereof.

(Manufacturing Method of Wiring Substrate)

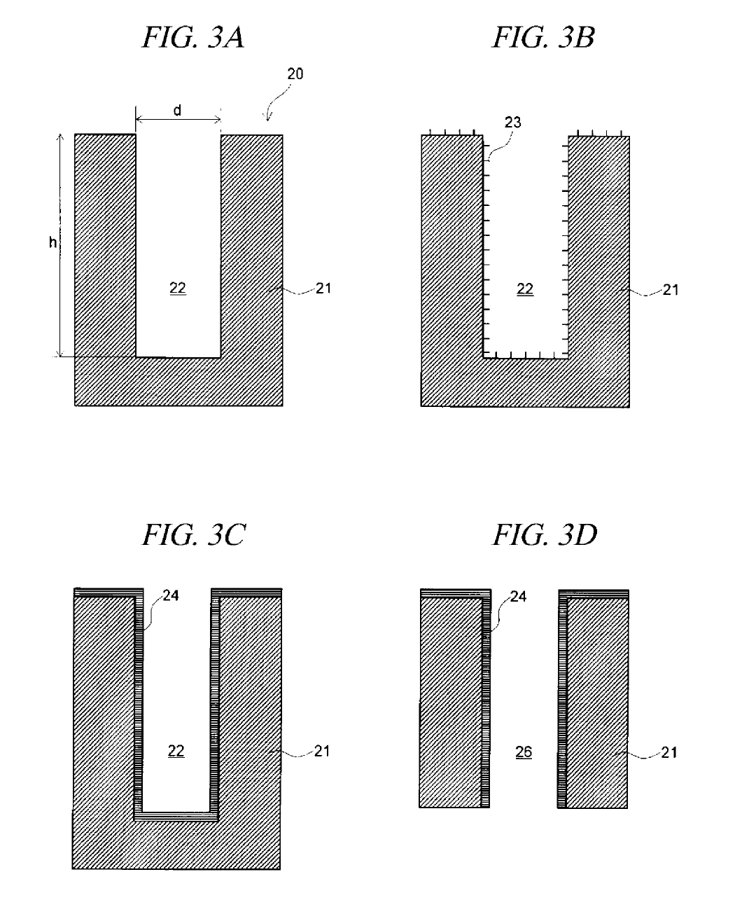

Hereinafter, an operation of the present example embodiment with the above-described configuration will be explained. Herein, a method of manufacturing a wiring substrate will be explained with reference to FIG. 3A to FIG. 3D.

As depicted in FIG. 3A, the substrate 20 in which a recess 22 is formed is prepared. A method of preparing the substrate 20 in which the recess 22 is formed is not particularly limited. By way of example, an insulating layer 21 is formed first by the coating/developing device 2, a mask is formed on the insulating layer 21 by the coating/developing device 2 and the exposure device 3, and then, the insulating layer 21 is etched by the etching device 4. Thus, the substrate 20 including the insulating layer 21 in which the recess 22 is formed can be obtained. A material of the insulating layer 21 is not particularly limited as long as a desired insulation property can be achieved. By way of example, an organic polymer or an inorganic insulating material such as silicon dioxide may be used.

In accordance with the present example embodiment, as described above, the catalyst can be adsorbed to the lower portion of the recess 22 of the substrate 20 in a short time even if a diameter of the recess 22 is small. Therefore, desirably, a diameter d (see FIG. 3A) of the recess 22 formed in the insulating layer 21 of the substrate 20 is set to be in the range of about 100 nm to about 100 μm. Further, desirably, an aspect ratio (h/d) (see FIG. 3A) of the recess 22 is set to be about 1 or more.

(Adsorption Process)

Then, the substrate 20 is brought into contact with the catalyst solution 12 by the catalyst adsorption device 10. To be specific, as depicted in FIG. 2, the substrate 20 is immersed in the catalyst solution 12 stored in the catalyst solution tank 11 (immersion process). Thus, as depicted in FIG. 3B, a catalyst 23 is adsorbed to a surface of the substrate 20. Herein, in accordance with the present example embodiment, during the immersion process, a high frequency vibration is applied to the catalyst solution 12 by the high frequency oscillator 14. For this reason, the catalyst 23 can be sufficiently diffused to the lower portion of the recess 22 of the substrate 20. As a result, as depicted in FIG. 3B, the catalyst can be adsorbed to the lower portion of the recess 22 in a short time.

(Plating Process)

Thereafter, the plating device 6 forms a plating layer 24 on the surface of the substrate 20 to which the catalyst 23 is adsorbed. A method of forming the plating layer 24 is not particularly limited. By way of example, a plating solution tank (not illustrated) in which a plating solution is stored is prepared, and the substrate 20 is immersed in the plating solution tank. Thus, as depicted in FIG. 3C, the plating layer 24 is formed on the surface of the substrate 20 by the electroless plating method.

A material forming the plating layer 24 is appropriately selected depending on a use of a semiconductor device, and for example, copper may be used. In this case, the plating solution contains copper salts serving as a copper ion source, such as copper sulfate, copper acetate, copper chloride, copper bromide, copper oxide, copper hydroxide, copper pyrophosphat, and the like. The plating solution further contains a complexing agent and a reducing agent of copper ions. Furthermore, the plating solution may contain various additives for improving stability or speed of a plating reaction.

(Chemical Mechanical Polishing Process)

Hereinafter, a rear side (a side to which the recess 22 is not exposed) of the insulating layer 21 is chemically and mechanically polished, so that the recess 22 is exposed to the rear side of the insulating layer 21. Thus, as depicted in FIG. 3D, a wiring substrate on which the plating layer 24 is formed and which includes a through-via-hole 26 is manufactured. Thereafter, although not illustrated, a process of forming a bump on the through-via-hole 26, a process of forming a preset pattern on the front surface or the rear surface of the insulating layer 21, or the like may be appropriately performed.

As such, in accordance with the present example embodiment, during the adsorption process where the substrate 20 is brought into contact with the catalyst solution 12, a high frequency vibration is applied to the catalyst solution 12. For this reason, the catalyst 23 can be diffused to the lower portion of the recess 22 of the substrate 20, so that the catalyst can be adsorbed to the lower portion of the recess 22 in a short time. Thus, the plating layer 24 can be uniformly formed to the lower portion of the recess 22.

Further, various modifications of the above-described example embodiment can be made. Hereinafter, modification examples will be explained.

### First Modification Example

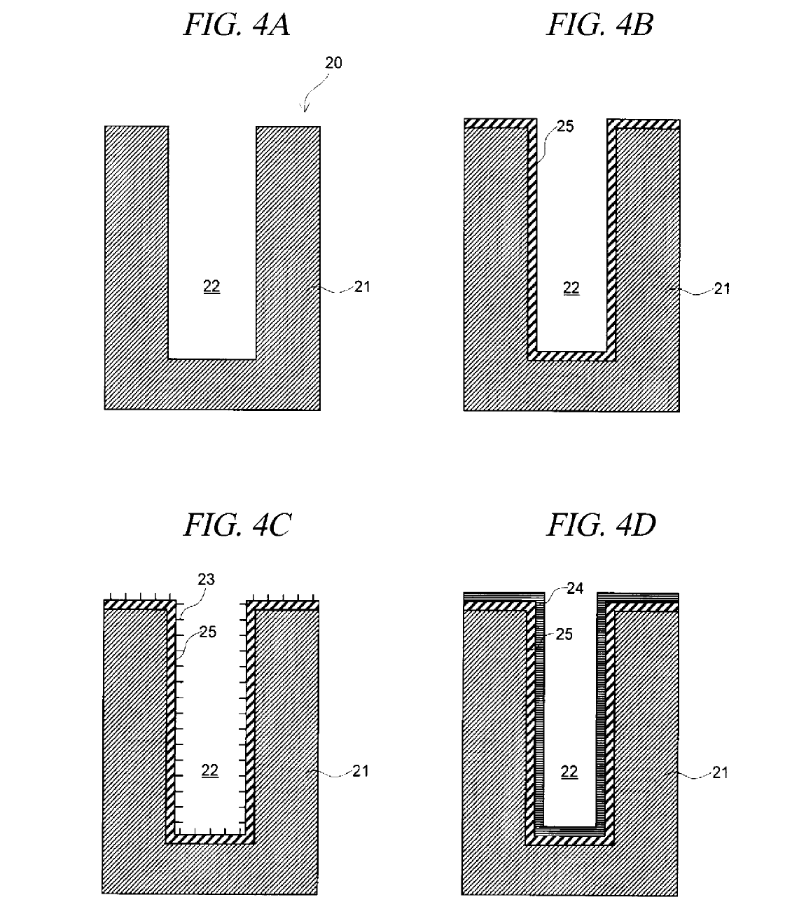

The above-described example embodiment illustrates an example where the catalyst 23 is adsorbed onto the insulating layer 21, but it is not limited thereto. By way of example, if a barrier film is formed on the surface of the substrate 20, the catalyst 23 may be adsorbed onto the barrier film. Such an example will be explained with reference to FIG. 4A to FIG. 4D.

As depicted in FIG. 4A, the substrate 20 including the insulating layer 21 in which the recess 22 is formed is prepared. Then, as depicted in FIG. 4B, the barrier film forming device 5 forms a barrier film 25 on a surface of the insulating layer 21. The barrier film 25 is configured to suppress the plating layer 24 made of a conductive material such as copper from being permeated through the insulating layer 21, and the barrier film 25 is formed of, for example, a tantalum nitride film or the like. A method of forming the barrier film 25 on the surface of the insulating layer 21 is not particularly limited, and for example, a chemical vapor deposition method may be used.

Then, in the same manner as the above-described example embodiment depicted in FIG. 3B, the substrate 20 is brought into contact with the catalyst solution 12. Thus, as depicted in FIG. 4C, the catalyst 23 can be sufficiently adsorbed onto the lower portion of the recess 22 on the barrier film 25. Then, as depicted in FIG. 4D, the plating layer 24 is formed on a surface of the barrier film 25 to which the catalyst 23 is adsorbed. Thus, the plating layer 24 can be uniformly formed on the lower portion of the recess 22.

### Second Modification Example

Further, the above-described example embodiment illustrates an example where the recess 22 of the substrate 20 is a non-through hole formed in the insulating layer 21, but it is not limited thereto. In accordance with the adsorption method and the adsorption device of the present example embodiment, regardless of whether the recess 22 of the substrate 20 is a through hole or a non-through hole, the catalyst can be adsorbed to the lower portion of the recess 22 in a short time.

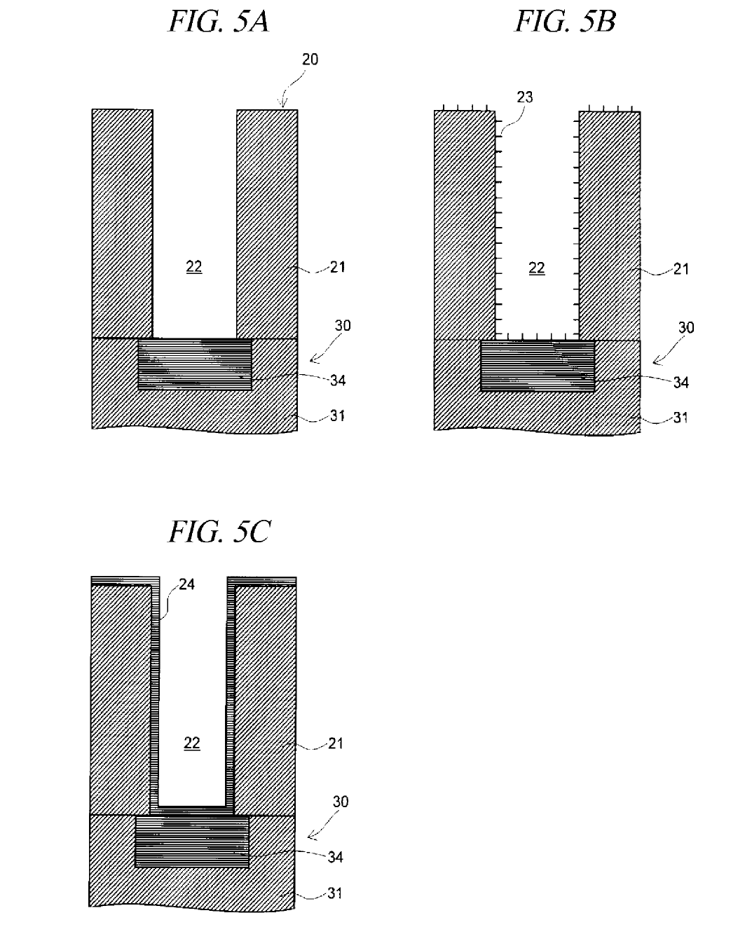

By way of example, as depicted in FIG. 5A, the recess 22 of the substrate 20 may be a through hole formed in the insulating layer 21 of the substrate 20. In this case, the substrate 20 may be supported from the below by another wiring substrate 30. The another wiring substrate 30 includes, for example, an insulating layer 31 and a wiring layer 34 made of a conductive material such as copper. Here, the wiring layer 34 is connected to the recess 22 of the substrate 20, as depicted in FIG. 5A.

In the modification example as depicted in FIG. 5A to FIG. 5C, the substrate 20 is brought into contact with the catalyst solution 12 in the same manner as the above-described example embodiment depicted in FIG. 3B. Thus, as depicted in FIG. 5B, the catalyst 23 can be sufficiently adsorbed to a side surface of the recess 22 and an upper surface of the another substrate. Thus, in a subsequent plating process, as depicted in FIG. 5C, the plating layer 24 can be uniformly formed to the lower portion of the recess 22.

(Other modification example) Furthermore, the present example embodiment and each of the modification examples describe an example where the plating layer 24 is formed only in the vicinity of the side surface of the recess 22 of the substrate 20 by a plating process, but they are not limited thereto. A plating process may be performed such that a conductive material such as copper can be buried in the entire space within the recess 22 of the substrate 20. In this case, an electroplating process, in which the plating layer 24 is used as a seed layer formed in the vicinity of the side surface of the recess 22, may be performed.

Further, the present example embodiment and each of the modification examples describe an example where a catalyst for a conductive material, such as copper, constituting a wiring of the semiconductor device is adsorbed to the side surface of the recess 22 of the substrate 20, but they are not limited thereto. Even when a catalyst for other purposes is adsorbed to the side surface of the recess 22 of the substrate 20, the adsorption method and the adsorption device in accordance with the present example embodiment and each of the modification examples may be used. By way of example, when a catalyst for an alloy of tungsten and cobalt, that is formed on the surface of the recess 22 of the substrate 20 as an underlayer of copper, is adsorbed to the side surface of the recess 22 of the substrate 20, the adsorption method and the adsorption device in accordance with the present example embodiment and each of the modification examples may be used.

Furthermore, prior to the above-described catalyst adsorption process of adsorbing the catalyst 23 to the surface of the substrate 20, a coupling agent such as a silane coupling agent or the like may be adsorbed to the surface of the substrate 20. Thus, thereafter, the catalyst 23 can be easily adsorbed to the surface of the substrate 20.

Some modification examples of the above-described example embodiment have been explained, and multiple modification examples can be appropriately combined and applied.

### Experimental Example

Hereinafter, the present example embodiment will be explained in more detail with reference to experimental examples, but it is not limited to these experimental examples.

### Experimental Example 1

In the substrate 20 including the insulating layer 21 made of silicon dioxide, the recess 22 having a diameter of about 5 μm, and a depth of about 30 μm (i.e. an aspect ratio of about 6) is formed. Then, the substrate 20 is immersed in the catalyst solution 12 stored in the catalyst solution tank 11 (immersion process). Herein, by using the high frequency oscillator 14 provided within the catalyst solution tank 11, a high frequency vibration of about 37 kHz is applied to the catalyst solution 12.

<Composition of Catalyst Solution>

Palladium (0.1 wt %)

Dispersant (polyvinylpyrrolidone)

In this case, a catalyst is formed of nanoparticles which are made of palladium and have an average diameter (average particle diameter) of about 4 nm.

<Immersion Condition>

Temperature: room temperature

Immersion time: 5 minutes

### Comparative Example 1

The substrate 20 is immersed in the catalyst solution 12 stored in the catalyst solution tank 11 in the same manner as the experimental example 1 except that a high frequency vibration is not applied to the catalyst solution 12.

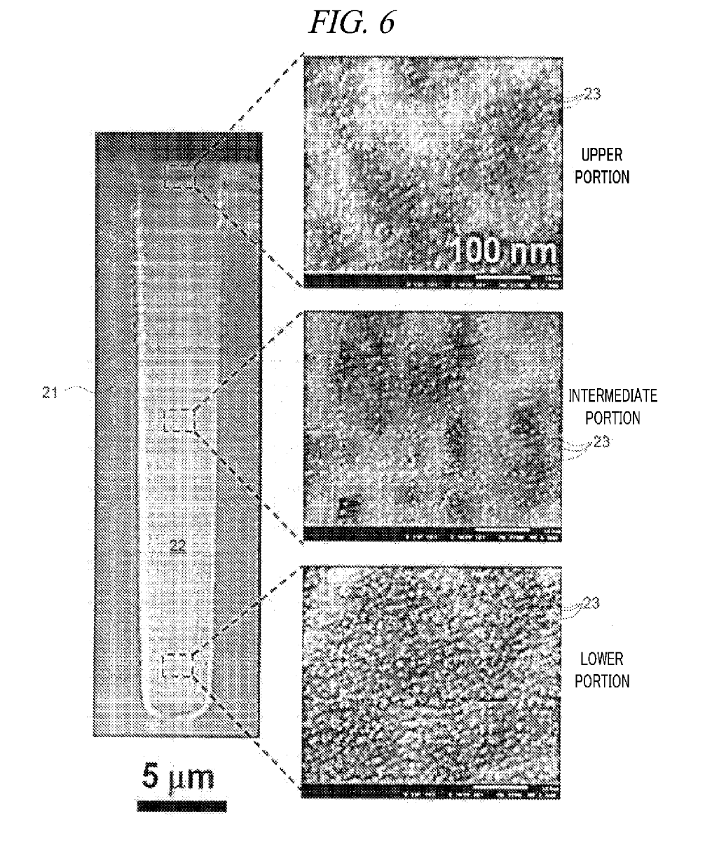

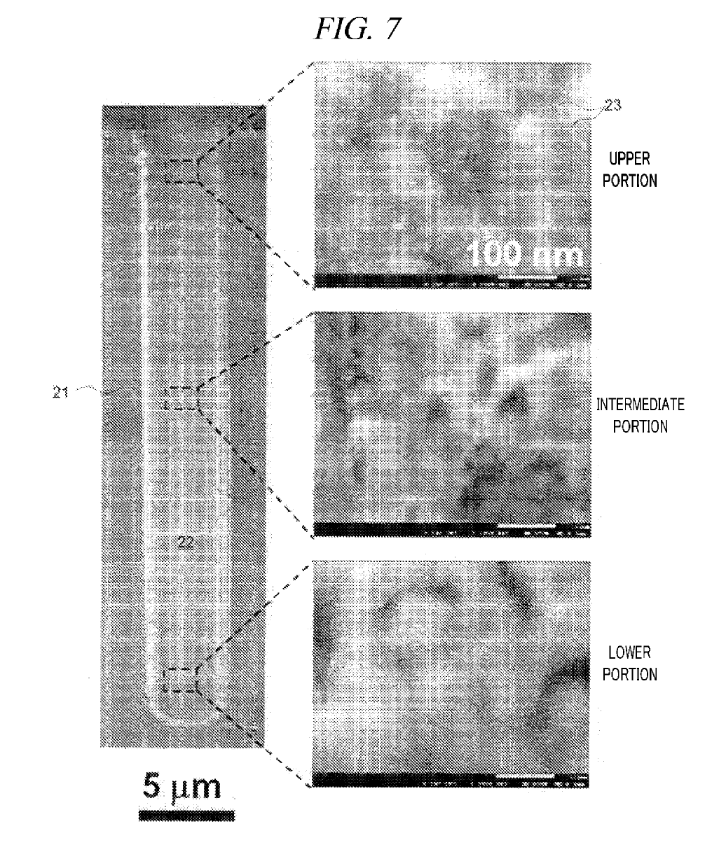

States of the catalyst 23 adsorbed to the side surface of the recess 22 of the substrate 20 in accordance with the experimental example 1 and the comparative example 1 are observed by SEM. The observation is carried out at an upper portion of the recess 22, i.e. in the vicinity of an opening of the recess 22, at the lower portion of the recess 22, i.e. in the vicinity of the bottom of the recess 22, and at an intermediate portion between the upper portion and the lower portion. An observation result obtained from the experimental example 1 is shown in FIG. 6, and an observation result obtained from the comparative example 1 is shown in FIG. 7.

As depicted in FIG. 6, in the experimental example 1, it is observed that the catalyst 23 is substantially uniformly adsorbed to the side surface of the recess 22 at the upper portion, the intermediate portion, and the lower portion of the recess 22. Meanwhile, as depicted in FIG. 7, in the comparative example 1, the catalyst 23 is hardly observed at the intermediate portion and the lower portion of the recess 22. In accordance with the experimental example 1, since a high frequency vibration is applied to the catalyst solution 12 during the immersion process, diffusion of the catalyst in the catalyst solution 12 can be accelerated, so that the catalyst 23 can be sufficiently adsorbed to the lower portion of the recess 22.

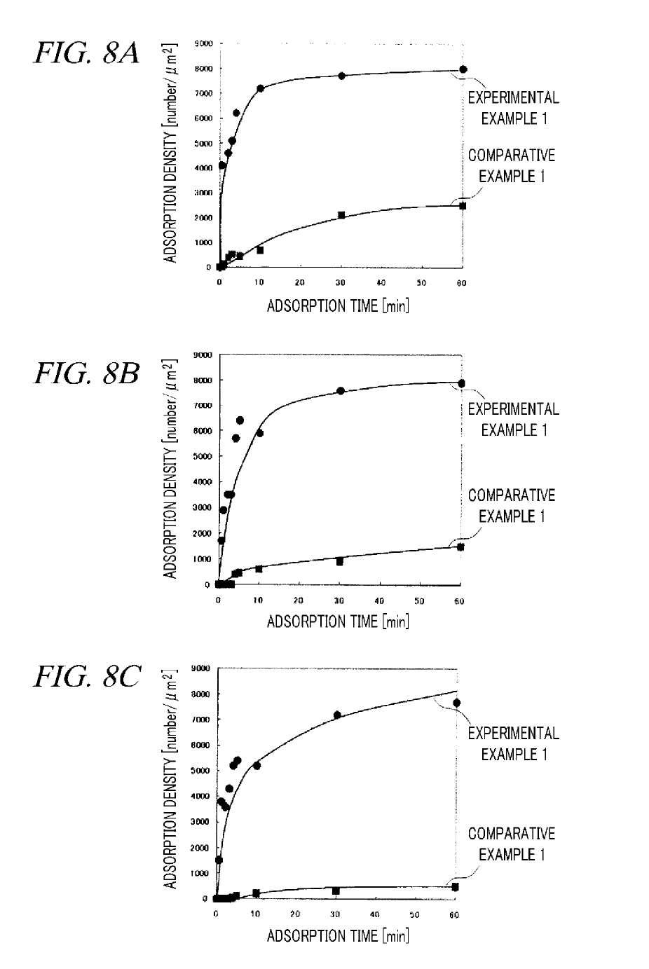

Further, relations between an adsorption time and a density of the catalyst 23 adsorbed to the side surface of the recess 22 of the substrate 20 in accordance with the experimental example 1 and the comparative example 1 are investigated. Further, the density of the catalyst 23 at each of time points is calculated by unloading the substrate 20 from the catalyst solution tank 11 at each time point, observing the side surface of the recess 22 by SEM, and counting the number of the catalysts 23 based on an image obtained. Measurement results are shown in FIG. 8A to FIG. 8C.

As depicted in FIG. 8A to FIG. 8C, in the experimental example 1, in about 5 minutes after the immersion process is started, the catalyst 23 having a sufficient density is adsorbed to the side surface of the recess 22. To be specific, in about 5 minutes after the immersion process is started, a density of the catalyst 23 reaches about 4000 catalysts/cm² or more. Meanwhile, in the comparative example 1, even in about 60 minutes after the immersion process is started, a density of the catalyst 23 does not reach about 4000 catalysts/cm². In accordance with the experimental example 1, since a high frequency vibration is applied to the catalyst solution 12 during the immersion process, diffusion of the catalyst in the catalyst solution 12 can be accelerated, so that the catalyst can be sufficiently adsorbed to the entire side surface of the recess of the substrate 20 in a short time.

The above-described experimental example 1 illustrates an example where the immersion process is performed at room temperature, but the present inventors also perform an immersion process in the same manner as the experimental example 1 except that a temperature of the catalyst solution 12 is set to be about 60° C. As a result thereof, when the catalyst 23 is observed by SEM and the relation between an adsorption time and a density of the catalyst 23 is measured, results substantially equivalent to those of the experimental example 1 are obtained. In this regard, it is found that by applying a high frequency vibration to the catalyst solution 12, adsorption of the catalyst 23 to the side surface of the recess 22 can be sufficiently accelerated regardless of a temperature.

### Experimental Example 2

The substrate 20 is immersed in the catalyst solution 12 stored in the catalyst solution tank 11 in the same manner as the experimental example 1 except that an immersion time is set to be about 1 hour.

### Experimental Example 3

The substrate 20 is immersed in the catalyst solution 12 stored in the catalyst solution tank 11 in the same manner as the experimental example 1 except that an immersion time is set to be about 3 hours.

### Comparative Example 2

In the substrate 20 including the insulating layer 21 made of silicon dioxide, the recess 22 having a diameter of about 3 μm, and a depth of about 25 μm (i.e. an aspect ratio of about 8) is formed. Then, the substrate 20 is immersed in the catalyst solution 12 stored in the catalyst solution tank 11 (immersion process). As the catalyst solution, a solution containing a colloid solution of palladium coated with tin chloride (hereinafter, referred to as Pd/Sn colloid solution) is used. Thereafter, as a post-treatment process, the substrate 20 is immersed in an acid accelerator containing sulfuric acid (10%) for about 20 minutes.

<Components of Catalyst Solution>

OPC-80 catalyst (Okuno Chemical Industries Co., Ltd.): 50 ml/L

OPC-SAL (Okuno Chemical Industries Co., Ltd.) M: 260 g/L

<Immersion Condition of Catalyst Solution>

Temperature: room temperature

Immersion time: 1 hour

### Comparative Example 3

The substrate 20 is immersed in the catalyst solution 12 stored in the catalyst solution tank 11 in the same manner as the comparative example 2 except that a high frequency vibration of about 37 kHz is applied to the catalyst solution during the immersion process.

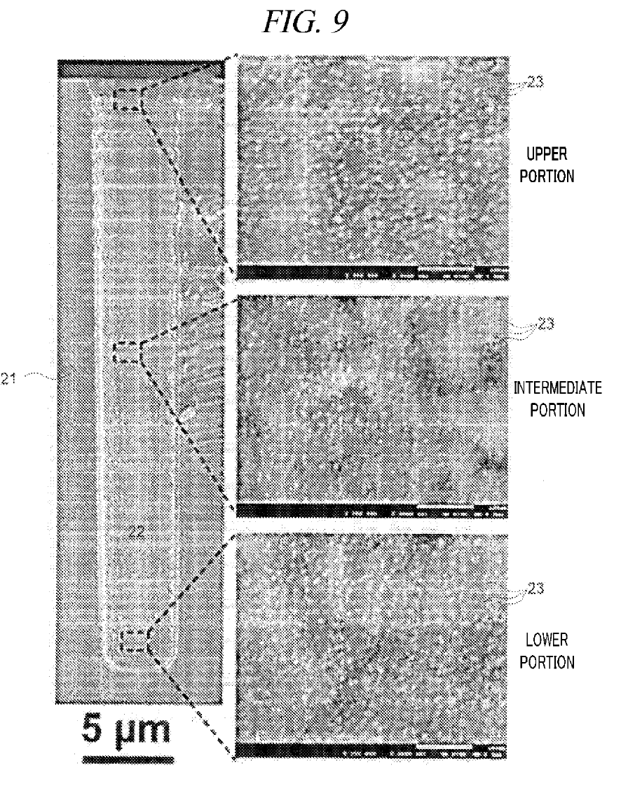

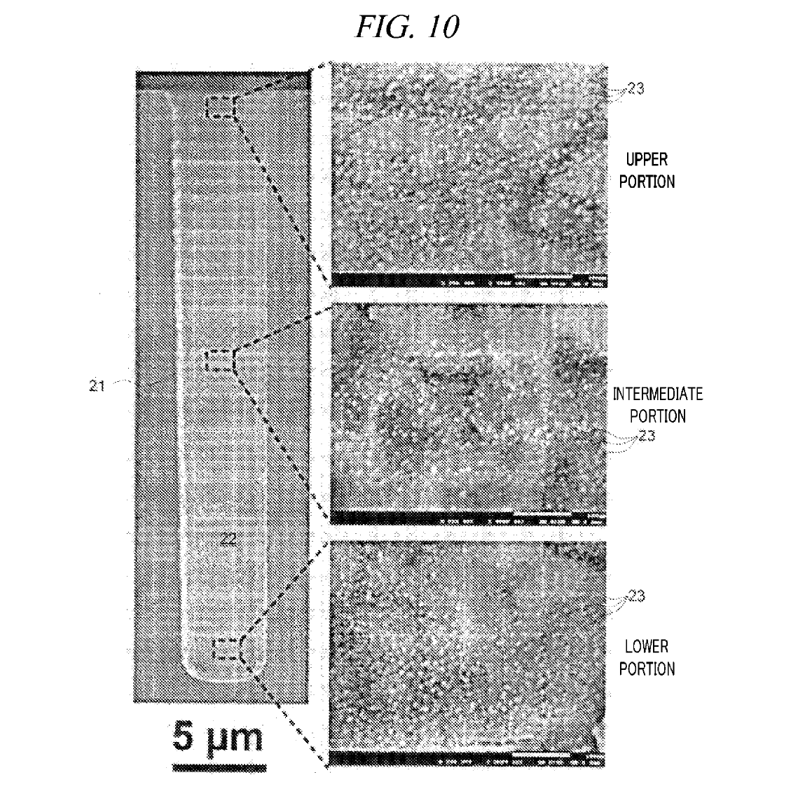

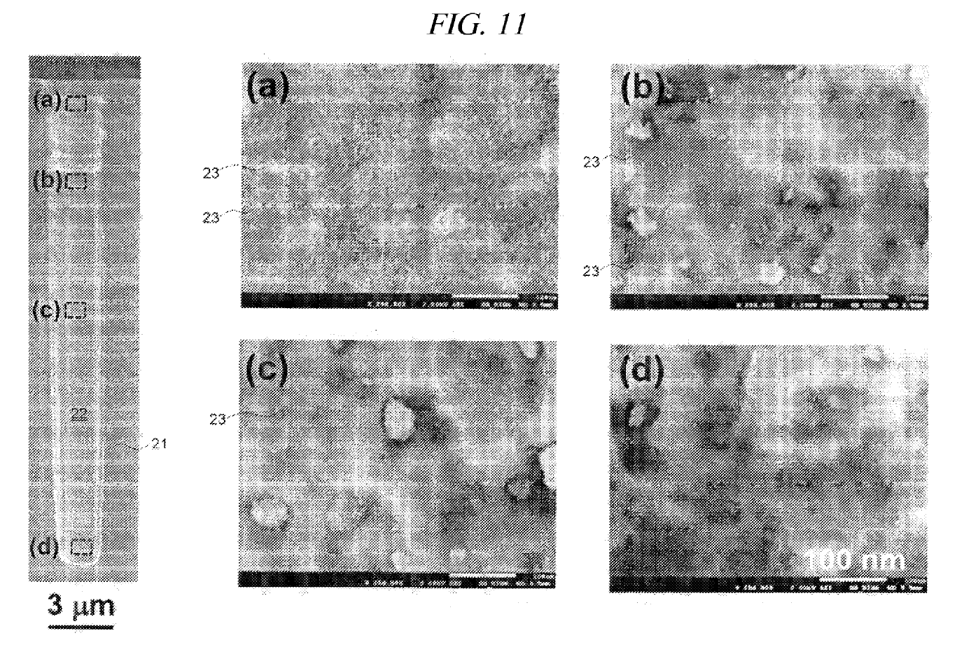

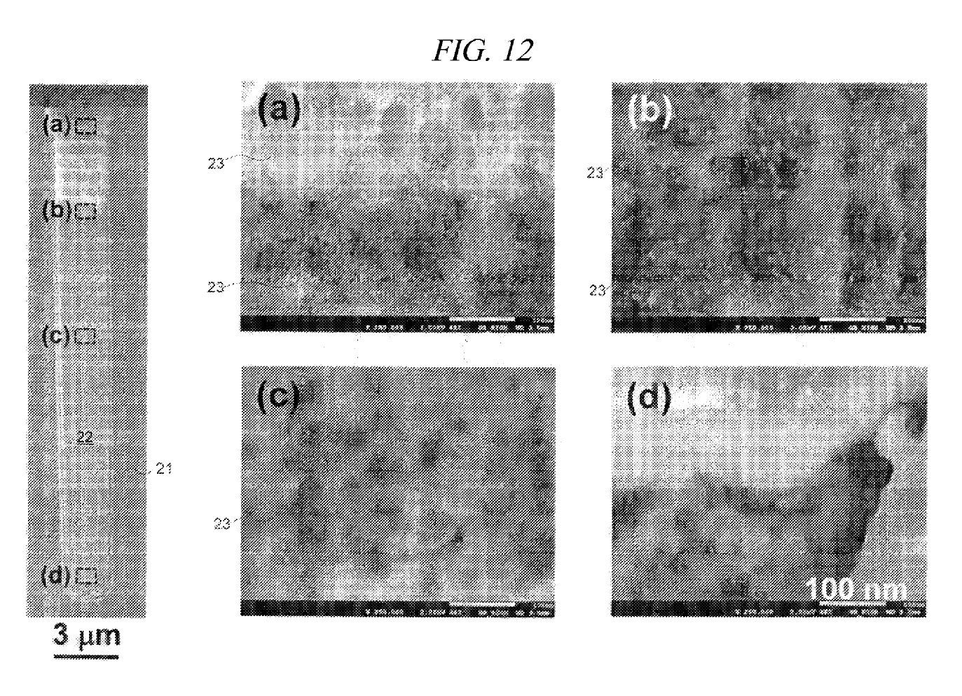

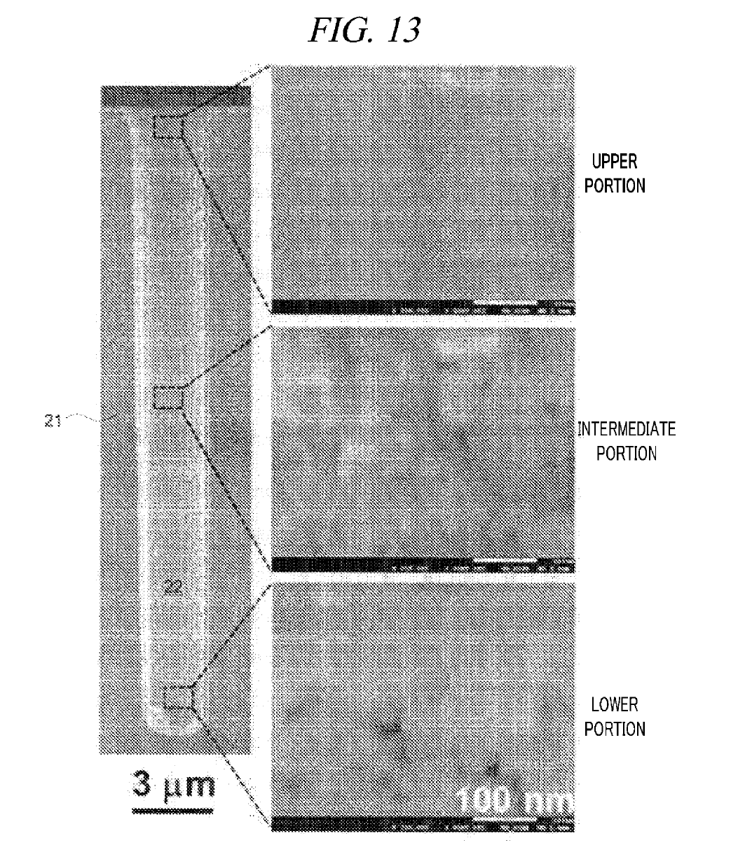

States of the catalyst 23 adsorbed to the side surface of the recess 22 of the substrate 20 in accordance with the experimental examples 2 and 3, and the comparative examples 2 and 3 are observed by SEM. The observation is carried out at the upper portion of the recess 22, i.e. in the vicinity of the opening of the recess 22, at the lower portion of the recess 22, i.e. in the vicinity of the bottom of the recess 22, and at the intermediate portion between the upper portion and the lower portion. Further, in the comparative examples 2 and 3, states of the catalyst 23 adsorbed to the side surface of the recess 22 are further observed at a portion between the upper portion and the intermediate portion of the recess 22. Observation results obtained from the experimental examples 2 and 3 are shown in FIG. 9 and FIG. 10, respectively, and observation results obtained from the comparative examples 2 and 3 are shown in FIG. 11 and FIG. 12, respectively. Images of (a), (c) and (d) in FIG. 11 and FIG. 12 show the observation results at the upper portion, the intermediate portion, and the lower portion of the recess 22, respectively. Further, images of (b) in FIG. 11 and FIG. 12 show the observation results at the portion between the upper portion and the intermediate portion of the recess 22. Furthermore, for the sake of comparison, FIG. 13 shows an observation result of the recess 22 of the substrate 20 before the immersion process is performed.

As depicted in FIG. 9 and FIG. 10, in the experimental examples 2 and 3, it is observed that the catalyst 23 is substantially uniformly adsorbed to the side surface of the recess 22 at the upper portion, the intermediate portion, and the lower portion of the recess 22. Further, agglomeration of nanoparticles is hardly seen.

Meanwhile, as depicted in FIG. 11, in the comparative example 2, Pd/Sn colloid agglomeration can be seen at the upper portion, the intermediate portion, and the lower portion of the recess 22. By way of example, within the recess 22, Pd/Sn colloid agglomeration of about 50 nm to about 100 nm are observed. In particular, the agglomeration is observed as a thick film at the upper portion of the recess 22. Meanwhile, a density of the Pd/Sn colloid adsorbed to the side surface of the recess 22 is decreased toward the lower portion of the recess 22.

As depicted in FIG. 12, in the comparative example 3, Pd/Sn colloid agglomeration can be seen at the upper portion, the intermediate portion, and the lower portion of the recess 22, although it is slight as compared with the comparative example 2. By way of example, within the recess 22, Pd/Sn colloid agglomeration of about 10 nm to about 20 nm is observed. In particular, the agglomeration is observed as a thick film at the upper portion of the recess 22. Meanwhile, a density of the Pd/Sn colloid adsorbed to the side surface of the recess 22 is decreased toward the lower portion of the recess 22. Further, in the comparative example 3, the immersion process is continuously performed for a long time, for example, for about 1 hour while applying the high frequency vibration in order to further adsorb the Pd/Sn colloid to the side surface of the recess 22. As a result, as time passes, agglomeration of the Pd/Sn colloid also proceeds. For this reason, in the comparative example 3, even if the immersion time is lengthened, the Pd/Sn colloid cannot be sufficiently adsorbed to the lower portion of the recess 22.

As shown in the comparative example 3, in the conventional adsorption process using the Pd/Sn colloid solution, it is generally known that application of a high frequency vibration to a catalyst may suppress the catalyst from being adsorbed. Meanwhile, as shown in the experimental examples 2 and 3, when a catalyst solution containing a catalyst formed of nanoparticles coated with a dispersant is used, even if the adsorption process (immersion process) is continuously performed for a long time while applying the high frequency vibration, agglomeration of the nanoparticles is hardly seen. That is, the present inventors have found that by using a catalyst solution containing a catalyst formed of nanoparticles coated with a dispersant, a high frequency vibration, which is effective in adsorbing the catalyst, can be applied while suppressing agglomeration of the catalyst.

Hereinafter, the findings obtained from the experimental examples 1 to 3 will be summarized. As shown in the experimental example 1, by applying a high frequency vibration to the catalyst solution 12 during the immersion process, the catalyst can be sufficiently adsorbed to the entire side surface of the recess of the substrate 20 even in a time as short as about 5 minutes. Further, as depicted in FIG. 8A to FIG. 8C, if the immersion process continues further, for example, for about 1 hour while applying the high frequency vibration, the catalyst 23 can be further adsorbed to the side surface of the recess of the substrate 20. Furthermore, as shown in the experimental examples 2 and 3, by using the catalyst solution containing the catalyst formed of the nanoparticles coated with the dispersant, it is possible to suppress agglomeration of the nanoparticles. Therefore, it is possible to independently set a time for an immersion process and also possible to independently control an adsorption density of the catalyst. This can be regarded as a remarkable effect as compared with the conventional catalyst adsorption method using a Pd/Sn colloid solution.

1. A catalyst adsorption method comprising:
preparing a substrate in which a recess is formed; and
adsorbing a catalyst formed of nanoparticles coated with a dispersant to a surface of the substrate by bringing the substrate into contact with a catalyst solution containing the catalyst,
wherein, in the adsorbing of the catalyst, a high frequency vibration is applied to the catalyst solution.

2. The catalyst adsorption method of claim 1,
wherein the dispersant includes polyvinylpyrrolidone (PVP), polyacrylic acid (PAA), polyethyleneimine (PEI), tetramethylammonium (TMA), or citric acid.

3. The catalyst adsorption method of claim 1,
wherein the nanoparticle includes palladium, gold, or platinum.

4. The catalyst adsorption method of claim 1,
wherein the nanoparticle includes ruthenium.

5. The catalyst adsorption method of claim 1,
wherein, in the adsorbing of the catalyst, the catalyst is adsorbed to a side surface of the recess of the substrate.

6. The catalyst adsorption method of claim 1,
wherein the adsorbing of the catalyst includes immersing the substrate in the catalyst solution containing the catalyst formed of the nanoparticles.

7. The catalyst adsorption method of claim 1,
wherein a diameter of the recess formed in the substrate is set to be in a range of from about 100 nm to about 100 μm.

8. A catalyst adsorption device comprising:
a substrate holding unit configured to hold a substrate in which a recess is formed;
a catalyst solution supplying unit configured to supply a catalyst solution containing a catalyst formed of nanoparticles coated with a dispersant to the substrate to bring the substrate into contact with the catalyst solution; and
a high frequency vibrating unit configured to apply a high frequency vibration to the catalyst solution supplied to the substrate.

9. The catalyst adsorption device of claim 8,
wherein the dispersant includes polyvinylpyrrolidone (PVP), polyacrylic acid (PAA), polyethyleneimine (PEI), tetramethyl ammonium (TMA), or citric acid.

10. The catalyst adsorption device of claim 8,
wherein the nanoparticle includes palladium, gold, or platinum.

11. The catalyst adsorption device of claim 8,
wherein the nanoparticle includes ruthenium.

12. The catalyst adsorption device of claim 8,
wherein the catalyst is adsorbed to a side surface of the recess of the substrate.

13. The catalyst adsorption device of claim 8,
wherein the catalyst solution supplying unit includes a catalyst solution tank in which the catalyst solution is stored, and
the high frequency vibrating unit includes a high frequency oscillator provided within the catalyst solution tank.

14. The catalyst adsorption device of claim 8,
wherein a diameter of the recess formed in the substrate is set to be in a range of from about 100 nm to about 100 μm.
